(19) United States
(12) Patent Application Publication
(10) Pub. No.: US 2015/0060704 A1
(43) Pub. Date: Mar. 5, 2015

(54) WRITING DATA CORRECTING METHOD, WRITING METHOD, AND MANUFACTURING METHOD OF MASK OR TEMPLATE FOR LITHOGRAPHY

(71) Applicant: KABUSHIKI KAISHA TOSHIBA, Tokyo (JP)

(72) Inventor: Keisuke YAGAWA, Yokohama Kanagawa (JP)

(21) Appl. No.: 14/453,877

(22) Filed: Aug. 7, 2014

(30) Foreign Application Priority Data
Sep. 4, 2013 (JP) 2013-183499

(51) Int. Cl. H01J 37/317; H01J 37/304; H01J 37/302

(52) U.S. Cl. CPC H01J 37/3175; H01J 37/3026; H01J 37/304; H01J 2237/0835
USPC 250/492.22

(57) ABSTRACT

According to one embodiment, a writing data correction method includes preparing a data table having a combination of a pattern resizing amount, a beam irradiation amount, and a back-scattering coefficient for each pattern size; converting, into writing data, a layout obtained by dividing a design layout into a plurality of regions in accordance with each pattern size, resizing patterns of the design layout writing based on the pattern resizing amounts corresponding to the pattern sizes contained in the respective regions, and executing a proximity effect correction for the resized patterns contained in the respective regions based on the beam irradiation amounts and the back-scattering coefficients corresponding to the pattern sizes of the design layout contained in the respective regions, and on the beam irradiation amounts and the back-scattering coefficients corresponding to the pattern sizes of the design layout contained in the regions adjacent to the respective regions.

### CROSS-REFERENCE TO RELATED APPLICATION

This application is based upon and claims the benefit of priority from Japanese Patent Application No. 2013-183499, filed September 4, 2013, the entire contents of which are incorporated herein by reference.

### FIELD

Embodiments described herein relate generally to a method for correcting data used to write a mask pattern, a feature writing method, and a manufacturing method for a mask or a template for lithography.

### BACKGROUND

A method using a variable shaped beam (VSB) system in an electron beam writing apparatus is used as a manufacturing method of a photo-mask for photolithography or a template for nanoimprint lithography that may be then be used in the manufacture of a semiconductor device. However, with the advancement of technologies for finer (smaller) structures and features in semiconductor devices, there is increasing difficulty in writing circuit patterns on a mask.

The VSB type electron beam writing method that is currently proposed resizes the patterns and establishes the magnitude of beam irradiation in accordance with the resized patterns to increase the contrast ratio of the beam intensity between a written or writing portion and a non-written or unwritten portion of the mask.

According to this method, however, highly accurate writing patterns are difficult to produce given the increasing degree of reduction in the size of the features of the patterns.

Accordingly, there is a need for a method capable of producing highly accurate writing patterns that may be used to produce increasingly finer written patterns.

### DESCRIPTION OF THE WRITINGS

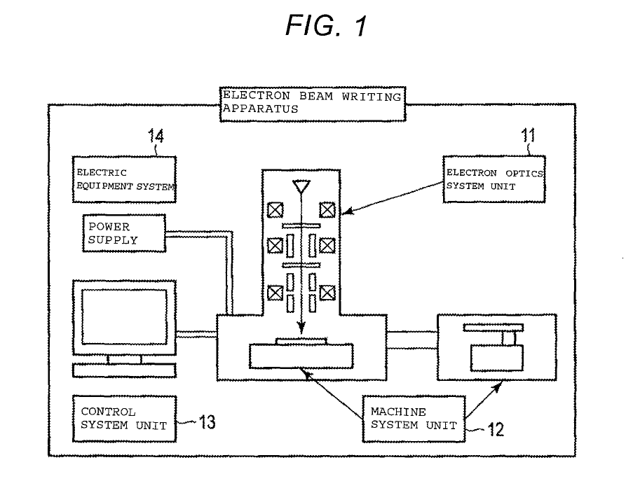

FIG. 1 illustrates the general structure of a variable shaped beam (VSB) system electron beam writing apparatus according to an embodiment.

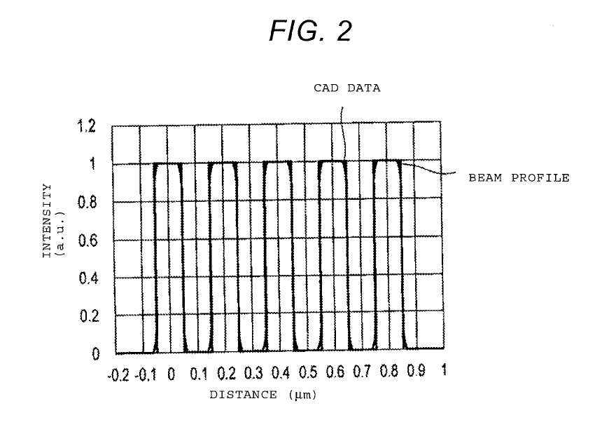

FIG. 2 shows a simulation result obtained when a line and space pattern (L/S pattern) with a half pitch of 100 nm is written.

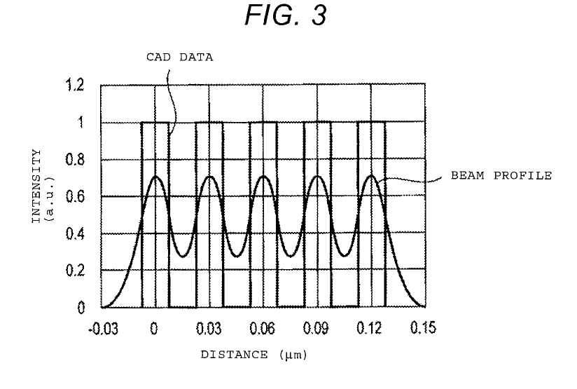

FIG. 3 shows a simulation result obtained when an L/S pattern with a half pitch of 15 nm is written.

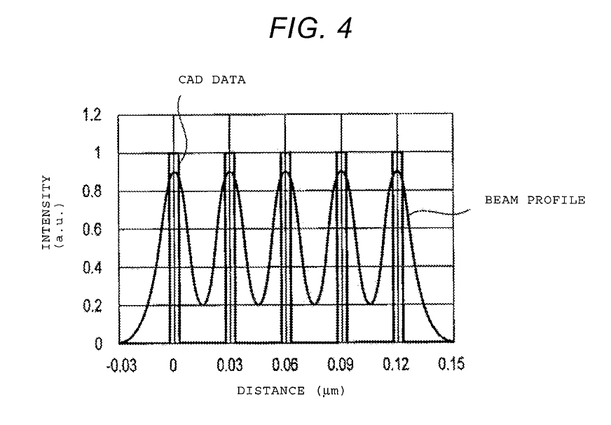

FIG. 4 shows a simulation result obtained when an L/S pattern with a half pitch of 15 nm that has been resized to 10 nm is written.

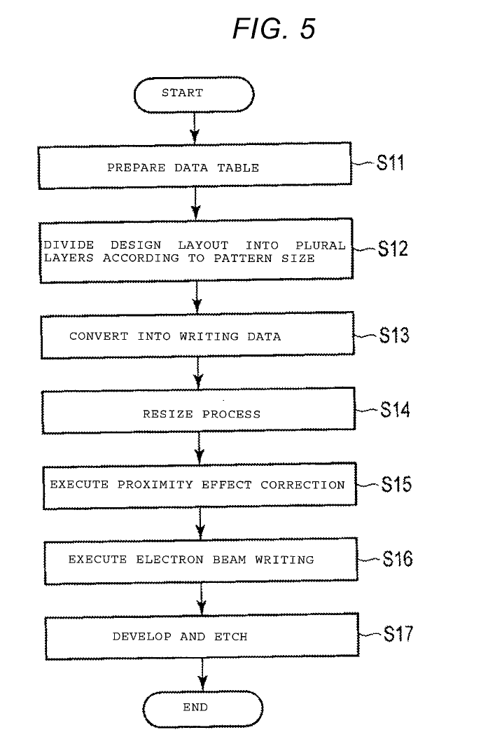

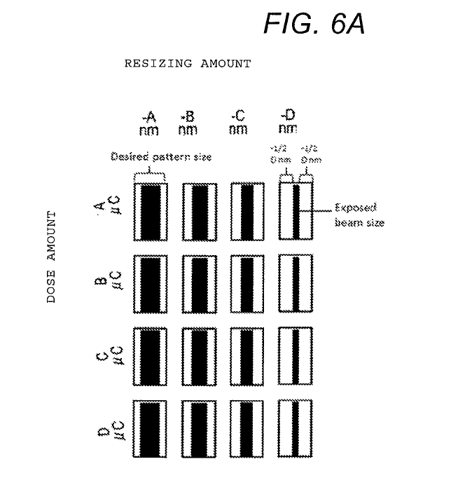

FIG. 5 is a flowchart showing a method according to the embodiment.

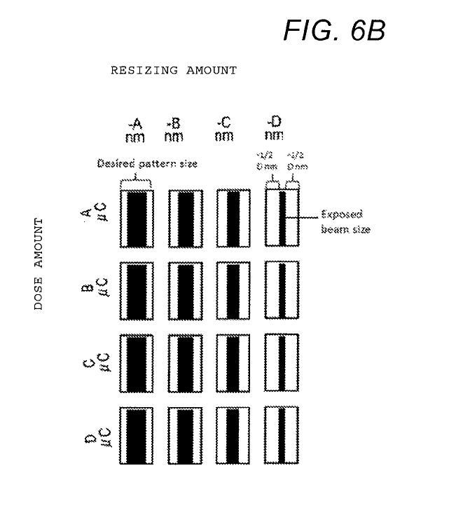

FIGS. 6A and 6B show examples of test patterns according to the embodiment.

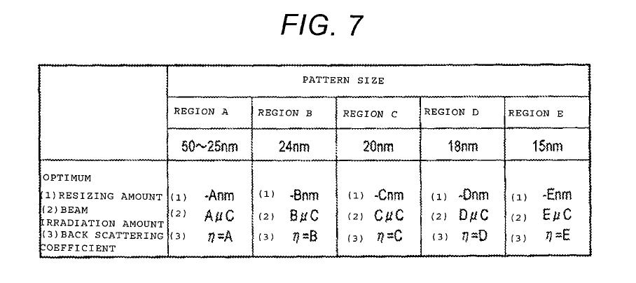

FIG. 7 shows an example of a data table according to the embodiment.

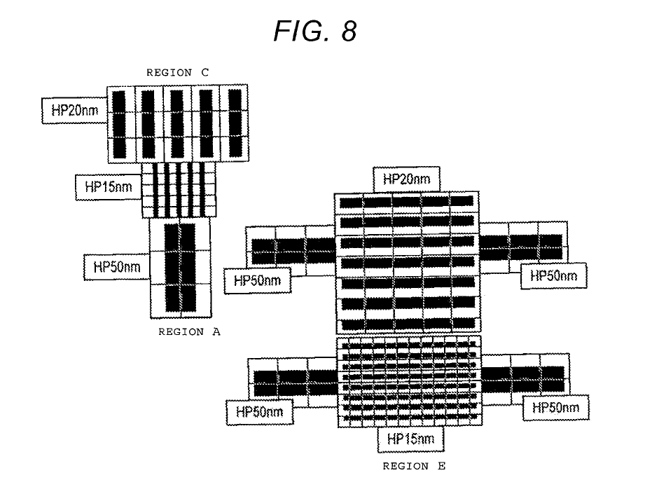

FIG. 8 illustrates an example which divides a design layout of a circuit pattern into a plurality of regions according to the embodiment.

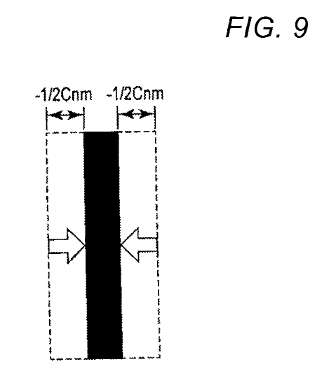

FIG. 9 illustrates an example of resizing according to the embodiment.

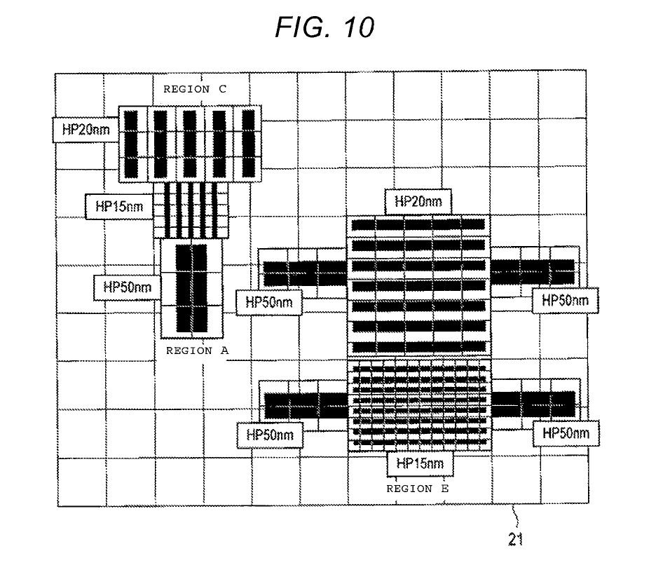

FIG. 10 illustrates an example which divides an area containing the design layout of the circuit pattern into a plurality of unit areas according to the embodiment.

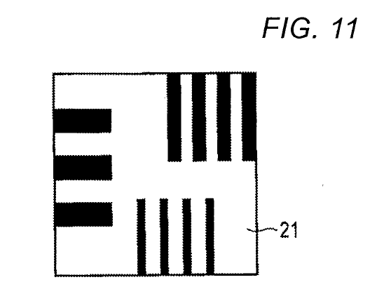

FIG. 11 illustrates an example in which a unit area contains patterns belonging to a plurality of different regions according to the embodiment.

### DETAILED DESCRIPTION

In general, according to one embodiment, a method capable of producing highly accurate writing patterns is provided.

According to one embodiment, a writing data correction method includes: preparing a data table specifying a combination of a pattern resizing magnitude, a beam irradiation magnitude, and a back-scattering coefficient for each pattern size for obtaining a desired pattern size after the pattern is written; converting into writing data a region-divided design layout obtained by dividing a design layout of a circuit pattern into a plurality of regions in accordance with each pattern size therein; resizing patterns of the design layout contained in the respective regions of the writing data based on the pattern resizing magnitudes within the data table corresponding to the pattern sizes of the design layout contained in the respective regions; and executing a proximity effect correction for the resized patterns contained in the respective regions based on the beam irradiation amounts and the back-scattering coefficients within the data table corresponding to the pattern sizes of the design layout contained in the respective regions, and on the beam irradiation amounts and the back-scattering coefficients within the data table corresponding to the pattern sizes of the design layout contained in the regions adjacent to the respective regions.

An exemplary embodiment is hereinafter described with reference to the drawings.

FIG. 1 illustrates the general structure of a variable shaped beam (VSB) system electron beam according to this embodiment. Discussed herein is the writing of photo-mask patterns on a mask substrate using the electron beam writing apparatus. However a similar method is applicable to writing of template patterns on an imprint substrate for nanoimprint lithography.

The electron beam writing apparatus shown in FIG. 1 includes an electron optics system unit 11, a machine system unit 12, a control system unit 13, and an electric equipment system 14.

The electron optics system 11 is constituted by an electron gun which generates electron beams and a deflector which deflects the electron beams for pattern writing and to “blank” the beam off of a substrate on which a pattern is being written, among other devices. The machine system unit 12 includes a structure for transferring mask substrates to or from a writing stage, among other devices. The control system unit 13 controls the respective units via a computing device (software/hardware, CPU, memory, supporting circuits and the like), and provides other control functions for the electron beam writing apparatus. The electric equipment system unit 14 includes a power supply among other supporting circuits.

According to the VSB system electron beam writing apparatus, the control system unit 13 executes data processing for converting the design layout of a circuit pattern into a plurality of figures (patterns) to be formed on a mask substrate using electron beams when receiving input of data on the design layout. More specifically, the design layout is resolved or converted into rectangular or triangular figures each having a size of about 1 μm or smaller. Then, writing information, such as beam irradiation positions and beam irradiation magnitudes (amounts), are created for the respective rectangular or triangular figures.

The electron optics system unit 11 executes shaping and deflection of electron beams and other processes based on the writing information. The machine system unit 12 shifts the position of a stage carrying a mask substrate based on the writing information in cooperation with the action of the electron optics system unit 11 to enable two-dimensional pattern writing across the mask surface.

In the condition noted above, electron beam writing is performed to pattern a resist formed on the mask substrate. The resist, after the process of electron beam writing, is developed to result in a patterned resist. Then, etching by using the resist pattern as a mask is carried out to produce a mask pattern (circuit pattern) on the mask substrate.

Problems arising when writing a fine pattern using the VSB system electron beam writing apparatus are now explained.

FIG. 2 shows a simulation result obtained when a line and space pattern (L/S pattern) with a half pitch of 100 nm is written. FIG. 3 shows a simulation result obtained when an L/S pattern with a half pitch of 15 nm is written. The number of line patterns is five for each case. The electron beam resolution is set at 10 nm for each case. The horizontal axis represents the distance in the pattern arrangement direction, while the vertical axis represents the intensity of electron beams entering the resist at the substrate surface.

As can be seen from FIG. 3, the beam resolution is insufficient to accurately reproduce the CAD data in the resist in the case of the L/S pattern with a half pitch of 15 nm. In this case, blurring of the beams is increased, while the contrast ratio between the writing portion and the non-writing portion decreases, i.e., in the region between the rectangular CAD DATA portions, an intensity of over about 0.3 a.u. is provided, and in the CAD DATA portions, where an intensity of 1.0 a.u. is desired, a maximum intensity is only about 0.7 a.u. is provided. Accordingly, a highly accurate mask pattern is difficult to produce.

The problems pointed out above may be reduced by resizing the pattern to take into account the effect of scattering and reflection and setting the beam irradiation amount in accordance with the resizing amount.

FIG. 4 shows a simulation result obtained when an L/S pattern with a half pitch of 15 nm is written using this method. The resizing amount is set at −10 nm. The beam irradiation amount is adjusted (increased) such that a desired size is obtained with the energy threshold set at 50%. In this case, the contrast ratio improves to approximately 1.5 times higher than that ratio when resizing is not executed.

However, when the pattern feature is very small, a highly accurate writing pattern is difficult to produce by using this method only. According to this embodiment, therefore, the following method is employed to produce a highly accurate desired writing pattern.

Before going to an explanation of the method according to this embodiment, proximity effect correction generally used for electron beam writing is explained herein.

According to the proximity effect correction generally executed for electron beam writing, a writing pattern is divided into a plurality of meshed unit areas in the first step. The size of each unit area is about 1 μm square. Then, approximation is performed for each unit area using a representative figure method. The representative figure method provides approximations by substituting one rectangular figure having an area equal to the sum of the areas of the figures contained in one unit area and positioned at the area central to all the figures contained in the corresponding unit area. The approximation of the proximity effect correction according to the representative figure method is expressed by the following equation (1)

E0=(1/2)*D(x,y)+η∫D(x′,y′)g(x−x′,y−y′)dx′dy′ (1)

In the equation (1), E0 corresponds to the accumulated energy of electron beams (charged particle beams) accumulated on the resist at an arbitrary position (x,y) on the resist, and becomes a constant value. In the equation, D(x,y) indicates the proximity effect correction irradiation amount of electron beams irradiated from the writing apparatus toward the position (x,y). Also, D(x,y) corresponds to the accumulated energy of electron beams irradiated to the position (x,y) and accumulated in the resist at the position (x,y). More specifically, the equation (1) is based on the understanding that half of the irradiation amount of the electron beams irradiated to the position (x,y)((½)×D(x, y)) is accumulated on the resist at the position (x,y). The second half of the right side of the equation (1) corresponds to the accumulated energy of electron beams irradiated from the writing apparatus to an arbitrary position (x′,y′) on the resist and accumulated at the position (x,y) by the proximity effect (back scattering). Moreover, in the equation (1), i indicates the proximity effect correction coefficient (back-scattering coefficient), while g indicates the proximity effect distribution. According to a typical electron beam writing apparatus (charged beam writing apparatus), the proximity effect distribution g is represented by Gaussian distribution, for example.

Generally, the resizing amount and the optimum beam irradiation amount in accordance with the resizing amount are dependent on the pattern size. Therefore, when a mixture of patterns having different sizes (regions requiring different optimum beam irradiation amounts) is contained within a unit area, the optimum irradiation amount is difficult to establish when substitution of the representative figure is used.

Accordingly, the following method is adopted in this embodiment for solving these problems in the representative figure method.

FIG. 5 is a flowchart showing the method according to this embodiment.

Initially, a data table is prepared for specifying a combination of the pattern resizing amount, the beam irradiation amount, and the back-scattering coefficient (proximity effect correction coefficient) for each pattern size to obtain the desired pattern size after writing (S11).

More specifically, as illustrated in FIGS. 6A and 6B, test patterns are prepared to determine the relationship between the resizing amount and the dose amount (beam irradiation amount). FIG. 6A shows the relationship between the resizing amount and the dose amount when the pattern size is 25 nm, while FIG. 6B shows the relationship between the resizing amount and the dose amount when the pattern size is 24 nm. The resizing amounts are −A(nm), −B(nm), −C(nm), and −D(nm). The dose amounts (beam irradiation amounts) are −A(μC), −B(μC), −C(μC), and −D(μC). The dark areas of the figure represent the region of beam overlap where the cumulative energy is sufficient to expose the resist.

FIG. 7 shows an example of a data table created based on the test results obtained by using the test patterns shown in FIGS. 6A and 6B.

As can be seen from FIG. 7, a region name is given to each pattern size (first letter in row (1), Resizing amount). More specifically, a region A has a pattern size from 50 to 25 nm, a region B has a pattern size of 24 nm, a region C has a pattern size of 20 nm, a region D has a pattern size of 18 nm, and a region E has a pattern size of 15 nm. In the case of the region A, the optimum resizing amount is −Anm, the optimum beam irradiation amount is AμC, and the optimum back-scattering coefficient (optimum proximity effect correction coefficient) η is η=A. As for the regions B through E, the optimum resizing amount, the optimum beam irradiation amount, and the optimum back-scattering coefficient η are determined in a similar manner. The optimum beam irradiation amount is the beam irradiation amount for obtaining the desired pattern size with the energy threshold set at 50%. The optimum beam irradiation amount corresponds to D(x,y) in equation (1). The data table thus created is stored in a data storing system within the control system unit 13 shown in FIG. 1.

For avoiding complication of the data table, the same irradiation amount condition may be uniformly determined for patterns of a pattern size not requiring resizing and pattern sizes larger than this pattern size. According to the example shown in FIG. 7, the same irradiation amount condition is determined for the pattern sizes of 25 nm or larger with the threshold set at 25 nm.

Next, a design layout of a circuit pattern (mask pattern) as an actual pattern desired to be written is prepared. Then, the design layout of the circuit pattern is divided into a plurality of regions in accordance with the pattern sizes (S12).

FIG. 8 shows an example which divides the design layout of the circuit pattern into a plurality of regions. According to the example shown in the figure, the region A is an area having patterns with a half pitch (HP) of 50 nm, the region C is an area having patterns with a half pitch (HP) of 20 nm, and the region E is an area having patterns with a half pitch (HP) of 15 nm.

Next, the region-divided design layout is converted into writing data recognizable by the writing apparatus while retaining the region information based on the data obtained in S12 (step S13). The writing data thus converted is inputted to the writing apparatus. This converted writing data is registered on a data storing disk within a control calculator constituting the control system unit 13 shown in FIG. 1.

Next, resizing is executed for the writing data. In this step, the patterns of the design layout contained in the respective regions are resized based on the pattern resizing amounts within the data table in correspondence with the pattern sizes of the design layout contained in the respective regions (step S14).

More specifically, the writing data registered on the data storing disk in the step S13 is transmitted to a resizing unit within the control system unit 13. The resizing unit executes resizing for the respective regions by the pattern resizing amounts corresponding to the pattern sizes of the respective regions. More particularly, the resizing amounts corresponding to the pattern sizes of the respective regions are read from the data table created in the step S11, and resizing is performed for the patterns of the respective regions.

FIG. 9 shows an example of resizing. For practicing the resizing, two directions, i.e., the x direction and the y direction crossing each other at right angles, are possible as the resizing direction. According to this example, resizing in the short side direction of each figure is carried out as illustrated in FIG. 9. For maintaining the pattern pitch without changing the pitch, one half (½) of the resizing amount (−Cnm) is allocated to both sides of the pattern as illustrated in FIG. 9. The writing layout data obtained by resizing is transmitted to an irradiation amount calculation unit within the control system unit 13.

Next, the proximity effect correction is executed for the resized patterns contained in the respective regions. According to this embodiment, the proximity effect correction is executed for the resized patterns contained in the respective regions based on the beam irradiation amounts and the back-scattering coefficients corresponding to the pattern sizes of the design layout contained in the respective regions. The proximity effect correction is also executed on the beam irradiation magnitude and the back-scattering coefficients corresponding to the pattern sizes of the design layout contained in the regions adjacent to the respective regions (step S15). The beam irradiation magnitude and the back-scattering coefficients corresponding to the pattern sizes discussed herein are specified in the data table shown in FIG. 7. The proximity effect correction in this step is now explained in detail.

Initially, the area containing the design layout of the circuit pattern is divided into a plurality of unit areas 21 as illustrated in FIG. 10. In this case, the proximity effect correction according to the equation (1) is executed when only patterns belonging to one region, i.e. are of the same size, are present in the one unit area 21.

In some cases, there exists the unit area 21 which contains patterns belonging to plural different regions (different sized features) as illustrated in FIG. 11. In this case, the proximity effect correction is executed for all the regions (feature sizes) contained in the unit area 21 based on the beam irradiation magnitude and the back-scattering coefficient corresponding to the pattern size of the pattern belonging to a target region. The proximity effect correction is also executed on the beam irradiation magnitude and the back-scattering coefficients corresponding to the pattern sizes of the patterns belonging to the regions other than the target region. More specifically, the calculation for the proximity effect correction is performed based on the following equations based on the regions shown in FIG. 10.

The region A feature correction is calculated from the following equation.

$$Ea = ( 1 / 2 ) * Da ( x , y ) + η a \int Da ( {x}^{′} , {y}^{′} ) g ( x - {x}^{′} , y - {y}^{′} ) d {x}^{′} d {y}^{′} + η c \int Dc ( {x}^{′} , {y}^{′} ) g ( x - {x}^{′} , y - {y}^{′} ) d {x}^{′} d {y}^{′} + η e \int De ( {x}^{′} , {y}^{′} ) g ( x - {x}^{′} , y - {y}^{′} ) d {x}^{′} d {y}^{′} \qquad ( 2 )$$

The region C feature correction is calculated from the following equation.

$$Ec = ( 1 / 2 ) * Dc ( x , y ) + η c \int Dc ( {x}^{′} , {y}^{′} ) g ( x - {x}^{′} , y - {y}^{′} ) d {x}^{′} d {y}^{′} + η a \int Da ( {x}^{′} , {y}^{′} ) g ( x - {x}^{′} , y - {y}^{′} ) d {x}^{′} d {y}^{′} + η e \int De ( {x}^{′} , {y}^{′} ) g ( x - {x}^{′} , y - {y}^{′} ) d {x}^{′} d {y}^{′} \qquad ( 3 )$$

The region E feature correction is calculated from the following equation.

$$Ee = ( 1 / 2 ) * De ( x , y ) + η e \int De ( {x}^{′} , {y}^{′} ) g ( x - {x}^{′} , y - {y}^{′} ) d {x}^{′} d {y}^{′} + η a \int Da ( {x}^{′} , {y}^{′} ) g ( x - {x}^{′} , y - {y}^{′} ) d {x}^{′} d {y}^{′} + η c \int Dc ( {x}^{′} , {y}^{′} ) g ( x - {x}^{′} , y - {y}^{′} ) d {x}^{′} d {y}^{′} \qquad ( 4 )$$

In the equations (2), (3), and (4), each of Ea, Ec, and Ee corresponds to the energy absorption coefficient or threshold of the resist, and becomes a constant value.

In the respective equations, each of Da(x,y), Dc(x,y), and De(x,y) corresponds to D(x,y) shown in the explanation of the equation (1). More specifically, Da(x,y) corresponds to D(x,y) of the region A, Dc(x,y) corresponds to D(x,y) of the region C, and De(x,y) corresponds to D(x,y) of the region E. In the respective equations, each of ma, ηa, and ηc, corresponds to η in the explanation of the equation (1). More specifically, ηa is the back-scattering correction coefficient of the region A, ηc is the back-scattering correction coefficient of the region C, and ηe is the back-scattering correction coefficient of the region E. Furthermore, in the respective equations, g(x−x′, y−y′) indicates the back-scattering effect distribution.

The values Da(x,y), Dc(x,y) and De(x,y) noted above correspond to the optimum beam irradiation amounts specified in the data table of FIG. 7. The values ηa, ηc, and ηe noted above correspond to the optimum back-scattering coefficients (optimum proximity effect correction coefficients) specified in the data table of FIG. 7.

The proximity effect correction is executed for all the regions contained in the unit area in the manner described above, based on the beam irradiation magnitude and the back-scattering coefficient for the arbitrary target region, and on the beam irradiation amounts and the back-scattering coefficients for the regions other than the target region. By this process, an irradiation amount map is created based on the proximity effect correction results. In other words, the irradiation amount calculation is performed in such a manner that the equations (2), (3) and (4) hold, thereafter the irradiation magnitude map is created based on the calculation.

Next, a shot figure creating unit within the control system unit 13 divides the writing data (writing figure) into divisions each having a predetermined shot size (area to be written or hit with e beam energy) based on the irradiation amount map obtained in the step S15. Then, a beam positioning calculation unit within the control system unit 13 shown in FIG. 1 determines the writing positions. After this determination, electron beam writing is executed for the resist (an electron beam photosensitive resist) formed on the mask substrate based on the writing information thus created (step S16).

Subsequently, the resist, after the writing, is developed to form a resist pattern. Then, etching is performed using the resist pattern as a mask to produce a photo-mask for lithography used for the manufacture of a semiconductor device or the like (step S17).

According to this embodiment, the proximity effect correction is executed based on the beam irradiation amounts and the back-scattering coefficients corresponding to the pattern sizes of the design layout contained in the respective regions, and on the beam irradiation amounts and the back-scattering coefficients corresponding to the pattern sizes of the design layout contained in the regions adjacent to the respective regions. In this case, the proximity effect correction is executed based on further consideration of the beam irradiation amounts and the back-scattering coefficients corresponding to the pattern sizes of the adjoining areas even when the areas having different pattern sizes are positioned adjacent to each other. Accordingly, the method of this embodiment produces a highly accurate writing pattern even when the pattern includes very small features.

The embodiment described herein may be modified in various manners.

According to the embodiment described herein, the data table may be created in accordance with the types of the resist for which writing is performed. Generally, the optimum resizing amount, the optimum beam irradiation amount, and other conditions are dependent on the types of the resist. Moreover, the process conditions, such as the development condition, and other conditions, such as the optimum resizing amount and the optimum beam irradiation amount, are changeable in accordance with the change of the types of the resist. Thus, plural data tables corresponding to the respective types of the resist may be prepared for each pattern size. These data tables, if prepared, allow execution of more accurate proximity effect correction, and therefore allow production of a highly accurate writing pattern.

According to the embodiment described herein, the data table specifying the combination of the pattern resizing amount, the beam irradiation amount, and the back-scattering coefficient is created for each pattern size. However, a data table specifying the combination of the pattern resizing amount, the beam irradiation amount, the back-scattering coefficient, and a writing multiplicity (explained below) may be prepared for each pattern size. In other words, the combination may further include the writing multiplicity in accordance with the pattern size.

In the process of writing, there is a possibility that a non-uniform writing portion is produced on the boundary (junction) between the adjoining shots. For overcoming this problem, a method known in the art divides the whole writing area into a plurality of writing parts and performs writing several times while shifting the writing position so as to reduce the non-uniform writing portion. The multiplicity of writing performed several times while shifting the writing position as in this method is called writing multiplicity.

The non-uniform writing portion becomes more significant as the pattern size decreases. On the other hand, multiple writing requires a longer time for completing the entire writing. Both the non-uniform writing portion and the writing time decrease when the writing multiplicity is specified in the data table in accordance with the pattern size.

According to the embodiment described herein, the example of a mask for photolithography (such as reflection type mask for EUV exposure) is exemplarily described. However, the method according to the embodiment described herein is applicable to the manufacture of a template for nanoimprint lithography, or other patterning processes.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A writing data correction method, comprising:
preparing a data table and storing the data table in a storage unit, the data table specifying a combination of a pattern resizing amount, a beam irradiation amount, and a back-scattering coefficient for each pattern size for obtaining a desired pattern size after writing of the pattern;
converting, into writing data, a region-divided design layout obtained by dividing a design layout of a circuit pattern into a plurality of regions corresponding to each pattern size in the design layout;
resizing patterns of the design layout contained in the respective regions of the writing data based on the pattern resizing amounts within the data table corresponding to the pattern sizes of the design layout contained in the respective regions; and
executing a proximity effect correction for the resized patterns contained in the respective regions based on the beam irradiation amounts and the back-scattering coefficients within the data table corresponding to the pattern sizes of the design layout contained in the respective regions, and on the beam irradiation amounts and the back-scattering coefficients within the data table corresponding to the pattern sizes of the design layout contained in the regions adjacent to the respective regions.

2. The method according to claim 2, wherein
the step of executing the proximity effect correction for the resized patterns contained in the respective regions comprises:
dividing an area containing the design layout into a plurality of unit areas.

3. The method according to claim 2, further comprising:
executing the proximity effect correction for each of the regions contained in an arbitrary unit area based on the beam irradiation amount and the back-scattering coefficient within the data table corresponding to the pattern size of the pattern belonging to a target region, and on the beam irradiation amount and the back-scattering coefficient within the data table corresponding to the pattern size of the pattern belonging to any of the regions other than the target region.

4. The method according to claim 1, wherein
the data table is set based the properties of the resist on which the writing is performed.

5. The method according to claim 1, wherein
the combination specified in the data table further comprises writing multiplicity.

6. The method of claim 5, wherein the pattern is written at least two times, and the e-beam energy used in each pattern writing step is less than the energy required to expose the resist.

7. A writing method, comprising:
preparing a data table specifying a combination of a pattern resizing amount, a beam irradiation amount, and a back-scattering coefficient for each pattern size for obtaining a desired pattern size after writing;
converting, into writing data, a region-divided design layout obtained by dividing a design layout of a circuit pattern into a plurality of regions in accordance with each pattern size;
resizing patterns of the design layout contained in the respective regions of the writing data based on the pattern resizing amounts within the data table corresponding to the pattern sizes of the design layout contained in the respective regions;
correcting the resized patterns contained in the respective regions based on the beam irradiation amounts and the back-scattering coefficients within the data table corresponding to the pattern sizes of the design layout contained in the respective regions, and on the beam irradiation amounts and the back-scattering coefficients within the data table corresponding to the pattern sizes of the design layout contained in the regions adjacent to the respective regions to provide a corrected writing data; and
writing a pattern on a resist based on the corrected writing data.

8. The method according to claim 7, wherein the correcting the resized patterns contained in the respective regions comprises executing a proximity effect correction for the resized patterns.

9. The method according to claim 8, wherein
executing the proximity effect correction for the resized patterns contained in the respective regions comprises:
dividing an area containing the design layout into a plurality of unit areas.

10. The method according to claim 8, further comprising:
executing the proximity effect correction for each of the regions contained in an arbitrary unit area based on the beam irradiation amount and the back-scattering coefficient within the data table corresponding to the pattern size of the pattern belonging to a target region, and on the beam irradiation amount and the back-scattering coefficient within the data table corresponding to the pattern size of the pattern belonging to any of the regions other than the target region.

11. A manufacturing method of a mask or a template for lithography, comprising:
preparing a data table specifying a combination of a pattern resizing amount, a beam irradiation amount, and a back-scattering coefficient for each pattern size for obtaining a desired pattern size after writing;
converting, into writing data, a region-divided design layout obtained by dividing a design layout of a circuit pattern into a plurality of regions in accordance with each pattern size;
resizing patterns of the design layout contained in the respective regions of the writing data based on the pattern resizing amounts within the data table corresponding to the pattern sizes of the design layout contained in the respective regions;
correcting the resized patterns contained in the respective regions based on the beam irradiation amounts and the back-scattering coefficients within the data table corresponding to the pattern sizes of the design layout contained in the respective regions, and on the beam irradiation amounts and the back-scattering coefficients within the data table corresponding to the pattern sizes of the design layout contained in the regions adjacent to the respective regions to provide a corrected writing data; and
developing a resist based on the corrected writing data.

12. The method according to claim 11, wherein the correcting the resized patterns contained in the respective regions comprises executing a proximity effect correction for the resized patterns.

13. The method according to claim 12, wherein
executing the proximity effect correction for the resized patterns contained in the respective regions comprises:
dividing an area containing the design layout into a plurality of unit areas.

14. The method according to claim 13, further comprising:
executing the proximity effect correction for each of the regions contained in an arbitrary unit area based on the beam irradiation amount and the back-scattering coefficient within the data table corresponding to the pattern size of the pattern belonging to a target region, and on the beam irradiation amount and the back-scattering coefficient within the data table corresponding to the pattern size of the pattern belonging to any of the regions other than the target region

15. A writing data correction method executed on a computer, the method comprising:
preparing a data table specifying a combination of a pattern resizing amount, a beam irradiation amount, and a back-scattering coefficient for each pattern size for obtaining a desired pattern size after writing;
converting, into writing data, a region-divided design layout obtained by dividing a design layout of a circuit pattern into a plurality of regions in accordance with each pattern size;
resizing patterns of the design layout contained in the respective regions of the writing data based on the pattern resizing amounts within the data table corresponding to the pattern sizes of the design layout contained in the respective regions; and
executing proximity effect correction for the resized patterns contained in the respective regions based on the beam irradiation amounts and the back-scattering coefficients within the data table corresponding to the pattern sizes of the design layout contained in the respective regions, and on the beam irradiation amounts and the back-scattering coefficients within the data table corresponding to the pattern sizes of the design layout contained in the regions adjacent to the respective regions,
wherein executing the proximity effect correction for the resized patterns contained in the respective regions comprises:
dividing an area containing the design layout into a plurality of unit areas, and
executing a proximity effect correction for each of the regions contained in an arbitrary unit area when patterns belonging to different regions are contained in an arbitrary unit area of the unit areas, the proximity effect correction being based on the beam irradiation amount and the back-scattering coefficient within the data table corresponding to the pattern size of the pattern belonging to a target region, and on the beam irradiation amount and the back-scattering coefficient within the data table corresponding to the pattern size of the pattern belonging to any of the regions other than the target region,
the data table being set in accordance with the type of a resist for which writing is performed, and
the combination specified in the data table further comprising writing multiplicity.

16. The method of claim 15, wherein the step of resizing includes the step of changing the size of a feature by changing the location of opposite sides of feature by an equal amount.

17. The method of claim 15, wherein the step of resizing includes the step of resizing a plurality of lines having a pitch, and the step of resizing includes changing the size of the lines without changing the pitch of the lines.
